(19) United States
(12) Patent Application Publication
(10) Pub. No.: US 2025/0029842 A1
(43) Pub. Date: Jan. 23, 2025

(54) ETCHANT AND METHOD FOR SELECTIVELY ETCHING TITANIUM DIOXIDE

(71) Applicant: Microsoft Technology Licensing, LLC, Redmond, WA (US)

(72) Inventors: Asbjørn Cennet Cliff Drachmann, Copenhagen (DK); Charles Masamed Marcus, Copenhagen (DK)

(73) Assignee: Microsoft Technology Licensing, LLC, Redmond, WA (US)

(21) Appl. No.: 18/709,461

(22) PCT Filed: Nov. 11, 2021
(86) PCT No.: PCT/US2021/059005

§ 371 Date: May 10, 2024

(51) Int. Cl. H01L 21/311; C09K 13/00

(52) U.S. Cl. CPC H01L 21/31111; C09K 13/00

(57) ABSTRACT

In some examples of the disclosed technology, a method comprises etching titanium dioxide selectively in the presence of aluminium oxide using an etchant. The etchant can be an aqueous solution of a base and a hydroperoxide. In some examples, the etchant is effective for removing titanium dioxide without destroying an aluminium oxide layer. Examples of an etchant for etching titanium dioxide are disclosed, where the etchant is an aqueous solution of ammonia and hydrogen peroxide, and in some examples the molar ratio of the ammonia to the hydrogen peroxide is in the range 1:34 to 1:38. Methods of etching titanium dioxide disclosed herein can be used to fabricate semiconductor-superconductor hybrid devices.

### BACKGROUND

Semiconductor nanowires proximitized by a superconductor are expected to host a topological phase of matter, provided the right conditions. This makes them a promising candidate as building blocks of a fault-tolerant quantum computer.

The topological phase manifests itself in the form of a pair of Majorana zero modes (“MZMs”) at the ends of the nanowire. Along the bulk of the wire, away from the ends, a gap in the single-electron spectrum is present. Experiments typically use tunneling spectroscopy at the ends of the nanowire to detect a zero-bias peak (“ZBP”) in tunneling conductance.

By forming a network of such nanowires and inducing the topological regime in parts of the network, it is possible to create a quantum bit which can be manipulated for the purpose of quantum computing. A quantum bit, also referred to as a qubit, is an element upon which a measurement with two possible outcomes can be performed, but which at any given time (when not being measured) can in fact be in a quantum superposition of the two states corresponding to the different outcomes.

A nanowire may take the form of an elongate portion of semiconductor material, having a length dimension many times greater than its width and thickness. A nanowire is a quasi-one-dimensional system. A layer of conventional superconductor is arranged on at least a portion of the nanowire.

To induce a topological phase, the nanowire is cooled to a temperature where the superconductor (e.g. aluminum) exhibits superconducting behavior. The superconductor causes a proximity effect in the adjacent semiconductor, whereby a region of the semiconductor near the interface with the superconductor also exhibits superconducting properties, that is, a superconducting pairing gap is induced in the adjacent semiconductor. MZMs are formed at two ends of the semiconductor-superconductor hybrid when a magnetic field is applied.

The role of the magnetic field is to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level spilt between the differently spin-polarized electrons. This is known as the Zeeman effect. The Zeeman energy, i.e. the magnitude of the energy level split, should be at least as large as the superconducting gap in order to close the trivial superconducting gap and reopen a topological gap in the system.

Inducing MZMs may also involve adjusting the electrostatic potential of charge carriers in the nanowire by gating the nanowire with an electrostatic potential. The electrostatic potential is applied using a gate electrode. Applying an electrostatic potential manipulates the number of charge carriers in the conductance band or valence band of the semiconductor component.

The electronic properties of a hybrid system are highly dependent upon the manner in which the device is fabricated. In particular, the quality of the interface between the semiconductor component and the superconductor component greatly influences the behaviour of the finished device. The fabrication of nanowire heterostructures comprising InAs and Al layers has been reported (Krogstrup, et al., Nat. Mater. 14, 400 (2015)).

### SUMMARY

In one aspect, the present disclosure provides a method, comprising etching titanium dioxide selectively in the presence of aluminium oxide using an etchant. The etchant is an aqueous solution of a base and a hydroperoxide. It has surprisingly been found that this etchant has good selectivity for titanium dioxide over aluminium oxide, and is effective for removing titanium dioxide without destroying an aluminium oxide layer.

In another aspect, there is provided an etchant for etching titanium dioxide, the etchant being an aqueous solution of ammonia and hydrogen peroxide, wherein the molar ratio of the ammonia to the hydrogen peroxide is in the range 1:34 to 1:38.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a flow diagram outlining an example method;

FIG. 2 is a schematic plan view of an example workpiece;

FIG. 3 is an annotated scanning electron microscopy, SEM, image of a device fabricated in accordance with Example 1;

FIG. 4 is a schematic plan view of the devices investigated using transport spectroscopy as described in Example 1;

FIG. 5 is a plot of differential conductance as a function of applied source-drain voltage for an example device (solid line) and a comparative device (dashed line) as measured by transport spectroscopy and discussed in Example 1;

FIG. 6 is an optical microscopy image of two workpieces prior to performing an etch as described in Example 2;

FIG. 7 is an optical microscopy image of workpieces following (a) a five-minute etch and (b) a ten-minute etch as described in Example 2;

FIG. 8 is an SEM image of a workpiece after a 5-minute etch as described in Example 2, annotated to identify masked (M) and exposed (E) regions of the workpiece;

FIG. 9 is an SEM image of a workpiece after a 10-minute etch as described in Example 2, annotated to highlight the approximate position of edges of the masked region;

FIG. 10 is an optical microscopy image of a workpiece following a 15-minute etch as discussed in Example 2;

FIG. 11 is an optical microscopy image of a workpiece following a 20-minute etch as described in Example 2;

FIG. 12 is an optical microscopy image of a workpiece used in the comparative example; and

FIG. 13 is an optical microscopy image of a workpiece following an etch in accordance with the comparative example.

All optical microscopy images were processed digitally to increase contrast and to convert them from colour to grayscale.

### DETAILED DESCRIPTION OF EMBODIMENTS

The verb ‘to comprise’ is used herein as shorthand for ‘to include or to consist of’. In other words, although the verb ‘to comprise’ is intended to be an open term, the replacement of this term with the closed term ‘to consist of’ is explicitly contemplated, particularly where used in connection with chemical compositions.

Volumes are measured at 25° C. under atmospheric pressure (1 atm; 101325 Pa).

Ionisation constants (e.g., pK_{b}) may be measured by potentiometric titration at 25° C. in 0.15 M aqueous potassium chloride solution.

One method for fabricating semiconductor-superconductor hybrid devices is described in co-pending International patent application no. PCT/EP2020/081723. The method involves forming a mask over an aluminium layer and then performing anodic oxidation to oxidise selectively portions of the aluminium layer which are not covered by the mask. One example of a mask material useful in this method is titanium, which is converted into titanium dioxide by the anodic oxidation.

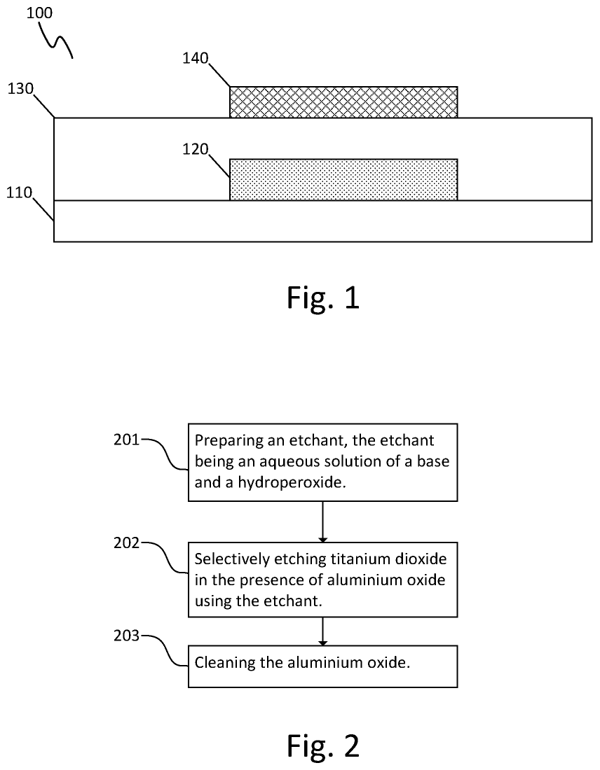

FIG. 1 illustrates an example device 100 which may be fabricated using this method. The device includes a substrate 110, which may comprise a semiconductor component; an aluminium component 120; an aluminium oxide layer 130; and a titanium oxide mask 140. The aluminium oxide layer 130 covers the aluminium component 120 and the substrate 110. The aluminium component 120 is arranged under the titanium oxide mask 140, with the aluminium oxide layer 130 extending between the aluminium component 120 and the titanium oxide mask 140.

The presence of any leftover titanium metal can be problematic during operation of the device. This can be avoided by selecting the conditions used in the anodic oxidation to oxidise fully the titanium mask, but this imposes an additional constraint on the fabrication process. It has been found that even the presence of titanium oxide can interfere with or prevent certain types of measurements of semiconductor-superconductor hybrid structures.

The aluminium oxide layer protects the semiconductor and superconductor components. In order to enhance performance of a hybrid device, the surface of the semiconductor component should be pristine. A method for removing mask 140 selectively, while retaining enough of the aluminium oxide layer 130 to protect the aluminium component 120 and substrate 110, is therefore desirable.

A dry, plasma etch using fluorine has been proposed as one technique for selectively etching titanium oxide in the presence of aluminium oxide. This technique is however potentially hazardous, and requires a specialised apparatus.

The use of wet etching would require an etchant which selectively removes titanium dioxide without also removing the aluminium oxide layer.

The inventors have surprisingly found that etchant in the form of an aqueous solution of a base and a hydroperoxide attacks titanium dioxide at a much greater rate than aluminium oxide, and can be used to etch titanium dioxide selectively in the presence of aluminium oxide. The etchant is also useful for etching titanium, since titanium is easily oxidised in situ.

Without wishing to be bound by theory, it is believed that the following reactions may take place when the aqueous solution is contacted with titanium or titanium oxide.

Any exposed titanium metal is oxidised to titanium dioxide by water, dissolved oxygen, and/or the hydroperoxide.

In the presence of the etchant, the titanium dioxide dissolves.

The dissolved titanium species reacts with the hydroperoxide, forming relatively soluble titanium (IV) complexes. Various different Ti(IV) complexes may be formed. The hydroperoxide may provide a source of one or more ligands selected from oxo ligands (O²⁻), superoxo ligands (O₂⁻), peroxo ligands (O₂²⁻), hydroperoxo ligands (ROOH), and peroxyl ligands (ROO—). Certain Ti(IV) complexes may further include one or more aqua and/or one or more hydroxyl ligands. The nature and relative proportions of the complexes obtained may vary depending upon the pH of the solution [Mori et al. Bulletin of the Chemical Society of Japan, vol. 29, no. 8, pp. 904-907].

Aluminium oxide can react with bases to form aluminium trihydroxide, Al(OH)₃. Aluminium trihydroxide is very poorly soluble in water. Aluminium trihydroxide can be hydrolysed to form aluminium tetrahydroxide anions, Al(OH)₄⁻, which are more soluble. Nevertheless, the present etchant has been observed to provide good selectivity for the removal of titanium. It is believed that the reaction of the aluminium oxide with the base is substantially slower than the reactions involving the titanium dioxide, and/or that the titanium complexes are substantially more soluble than the aluminium salts.

Aluminium oxide is not believed to react with hydroperoxides under the conditions used for etching processes. Commercially available stock solutions of concentrated hydrogen peroxide are often supplied in aluminium containers.

In the fabrication of semiconductor-superconductor hybrid devices according to the scheme described above, the function of the aluminium oxide layer is to protect the surface of the substrate and any semiconductor or superconductor components. Provided that these components remain protected, partial removal of the aluminium oxide layer and/or conversion of part of the protective layer from aluminium oxide to aluminium hydroxide is well-tolerated.

The thickness of the aluminium oxide layer may be selected such that, after the etch, the aluminium oxide layer has a thickness of at least 3 nm. This corresponds to the approximate depth of the native aluminium oxide layer which forms when aluminium is exposed to the air. An aluminium oxide layer with a thickness of 3 nm or greater provides very good protection to any components under the aluminium oxide layer. Aluminium oxide layers of arbitrary thickness can be formed by growing an aluminium layer, and then oxidising the aluminium layer by anodic oxidation.

An example method will now be explained with reference to FIG. 2. FIG. 2 is a flow diagram outlining the method.

At block 201, an etchant is prepared. Any suitable technique may be used. For example, an aqueous stock solution of the hydroperoxide may be diluted to a desired target concentration, and then mixed with a stock solution of the base.

At block 202, titanium dioxide is selectively etched in the presence of aluminium oxide using the etchant. This operation may comprise submerging a workpiece in the etchant, the workpiece including titanium dioxide and aluminium oxide. Both the titanium dioxide and the aluminium dioxide come into contact with the etchant.

The present method is particularly useful during the fabrication of semiconductor-superconductor hybrid devices. The workpiece may for example be a workpiece as described above with reference to FIG. 1. However, it will be appreciated that the present method may equally be used in other scenarios where etching titanium or titanium dioxide selectively in the presence of aluminium oxide is desired.

The etching may be performed at any temperature at which the etchant is in a liquid state. For example, the etching may be performed at about room temperature (20 to 30° C.).

The rate of etching may vary depending upon the concentration of the reagents in the etchant, and the temperature at which the etching is performed. The duration of the etch may be selected based on the rate of etching.

For example, an aqueous solution of ammonia at a concentration in the range 60 to 70 mM and hydrogen peroxide at a concentration in the range 1.8 to 2.2 M removed a 3 nm layer of titanium dioxide within about 15 minutes, with very little damage to an aluminium oxide layer with a thickness of greater than 8 nm.

It is possible to control the thickness of the aluminium oxide layer during the fabrication of the workpiece. For example, an aluminium layer of a desired thickness may be grown, and then oxidised by anodic oxidation to form the aluminium oxide layer. If the use of aggressive etching conditions (e.g., high temperature and/or high concentrations of base) is desired, then starting with a relatively thick aluminium oxide layer may mitigate the effect of any damage to the aluminium oxide layer.

The etching may be terminated by removing the workpiece from the etchant solution, and optionally washing the workpiece with a solvent, e.g. water.

At block 203, the aluminium oxide is cleaned. For example, the workpiece may be dipped in an acid bath. Hydrofluoric acid is one example of a suitable acid.

The surface of aluminium oxide may be damaged slightly by the etchant, or may pick up contaminants (e.g., precipitated aluminium hydroxide). Cleaning the surface may therefore be useful. The cleaning operation is however optional, and may be omitted in some implementations.

### Example 1

A workpiece of the type shown in FIG. 1 was fabricated in accordance with the method described in PCT/EP2020/081723. A semiconductor heterostructure including an indium arsenide quantum well layer for hosting a 2-dimensional electron gas, was prepared on a substrate. An epitaxial layer of aluminium was then grown over the semiconductor component and substrate in situ. The surface of the layer of aluminium was allowed to oxidise to form a native oxide layer. Anodic oxidation was performed to oxidize a partial thickness of the aluminium layer, thereby thinning the aluminium layer.

A 3 nm thick titanium mask was formed on the native oxide layer by evaporation and lift-off. The resultant workpiece was then treated by anodic oxidation, to oxidise selectively the portions of the aluminium layer not covered by the titanium mask. The titanium mask was also oxidised. The oxidation of the titanium mask may have occurred before the anodic oxidation, by exposure of the mask to air.

An etchant solution was prepared by mixing one part by volume of ammonia stock solution (25% ammonia by weight; 13.4 M), 50 parts by volume of a hydrogen peroxide stock solution (30% hydrogen peroxide by weight; 9.8 M); and 200 parts by volume of high purity deionised water. The stock solutions were obtained from Sigma-Aldrich and used without further purification.

The workpiece was submerged in the etchant solution for approximately 15 minutes at room temperature, before being washed with deionised water to terminate the etch.

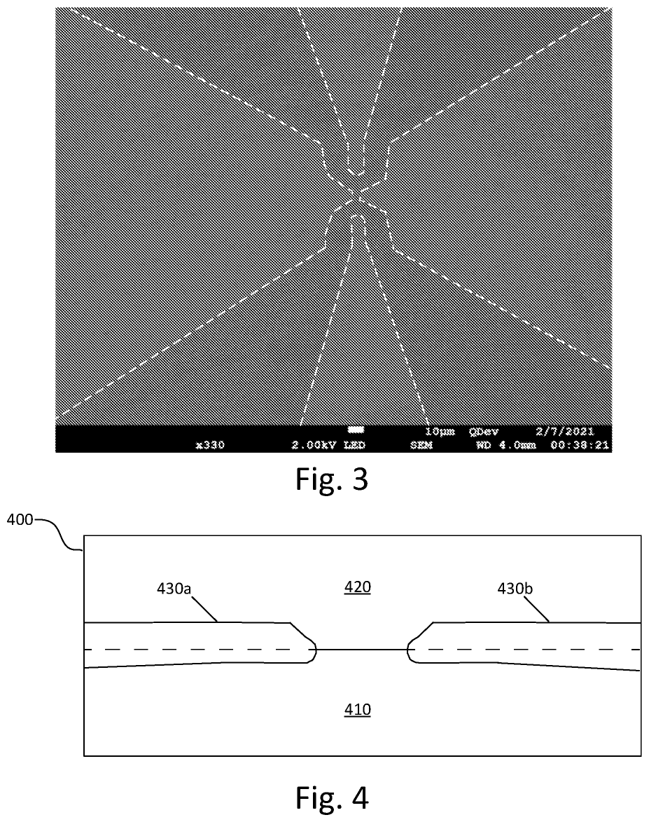

The workpiece was then investigated by scanning electron microscopy. An image of the work piece is shown in FIG. 3. Edges of the mask region have been annotated with a dashed line.

The dark regions in the image correspond to areas where the titanium mask was removed by the etchant. The light regions correspond to areas where the aluminium oxide layer was exposed. The colour gradient is an effect of differences in the thickness of the aluminium oxide layer between the two regions. It was observed that the titanium oxide mask was completely removed.

A gate stack was formed on the workpiece to produce a device as illustrated in plan in FIG. 4. A gate dielectric covering the surface of the workpiece was added. Two Ti/Au gate electrodes (430a, 430b) were formed on the gate dielectric. The gate electrodes 430a, 430b are spaced from one another to provide a quantum point contact. Each gate electrode 430a, 430b overlapped a boundary between a region 410 lacking a superconductor layer, and a region 420 having a superconductor layer.

A comparative device was also prepared. The comparative device had the layout illustrated in FIG. 4. Its aluminium component was not thinned, and was patterned by etching rather than by selective anodic oxidation. No titanium mask was used in the fabrication of the comparative device.

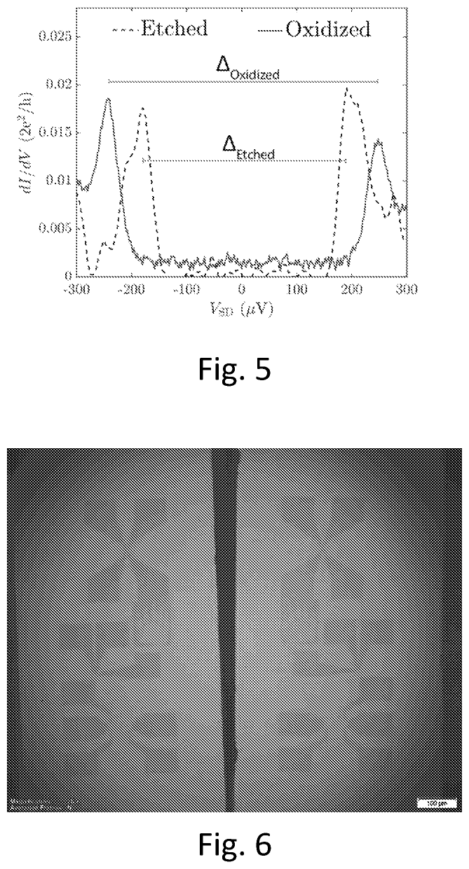

Transport spectroscopy measurements were performed on the two devices. The results are shown in FIG. 5. FIG. 5 is a plot of differential conductance as a function of voltage across the quantum point contact. The solid line shows the results for the example device. The dashed line shows the results for the comparative device.

A differential conductance of zero is a signature of the absence of fermionic states, in this case due to an induced superconducting pairing. The spacing A between the peaks in the differential conductance plot provides a measure of the size of the superconductive gap induced in the semiconductor. It is desirable for the induced gap to be as large as possible, since this may allow states of interest (e.g. MZMs) to be more stable.

A superconductive gap was induced in both devices. Removal of the titanium mask did not destroy the underlying superconductor component, further confirming that protective aluminium oxide layer remained over the superconductor component.

In fact, the device fabricated using anodic oxidation followed by removal of the Ti mask had a larger induced superconductive gap than the comparative device. This is believed to be due to reduction in thickness of the aluminium layer which is made possible by the use of anodic oxidation.

### Example 2

Four workpieces, each comprising a substrate, an aluminium oxide layer on the substrate, and a titanium dioxide mask on the aluminium oxide layer were prepared. The titanium dioxide mask was formed by depositing a 3 nm thick titanium layer and patterning the mask by lift-off. The titanium layer was allowed to oxidise to titanium dioxide by exposure to air.

Optical micrographs of two of the workpieces were captured. A contrast adjustment filter was applied, and the images were converted to black-and-white. The images are shown in FIG. 6. The mask is visible as dark grey regions on the lighter aluminium oxide.

An etchant solution was prepared by mixing one part by volume of ammonia stock solution (25% ammonia by weight; 13.4 M), 50 parts by volume of a hydrogen peroxide stock solution (30% hydrogen peroxide by weight; 9.8 M); and 200 parts by volume of high purity deionised water.

The workpieces were submerged in the etchant at room temperature. Individual workpieces were removed after 5, 10, 15 and 20 minutes, and rinsed to terminate the etch. An optical micrograph and an SEM image of each workpiece was captured. The images were processed by applying a contrast adjustment filter and then converting the images to black-and-white.

FIG. 7 shows optical micrographs of workpieces removed after (a) 5 minutes and (b) 10 minutes.

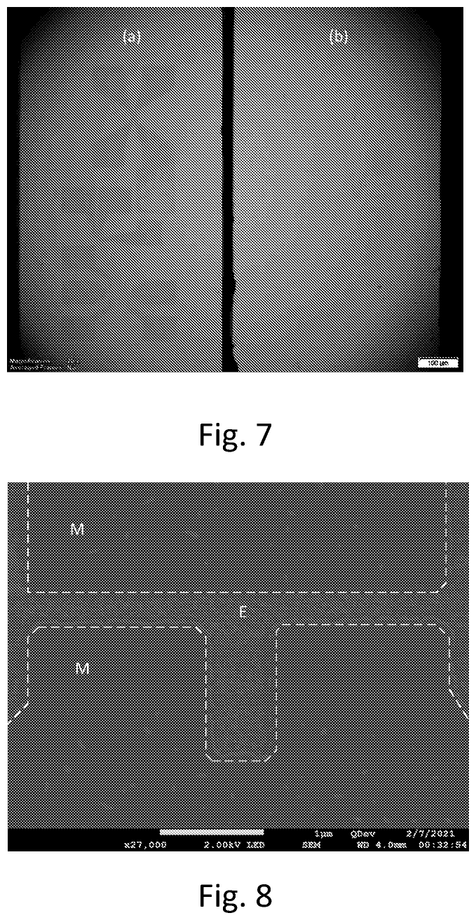

After 5 minutes (workpiece (a) of FIG. 7), the titanium mask remained visible. The mask is also clearly visible in the SEM image (FIG. 8).

After 10 minutes, (workpiece (b) of FIG. 7) the etchant had attacked the titanium mask. Some remnants of the titanium mask remained visible. This was confirmed by SEM. The SEM image is shown in FIG. 9, with the approximate position of the mask being highlighted with a white dashed line. The Ti mask appears to be patchy in places, but is still just about visible.

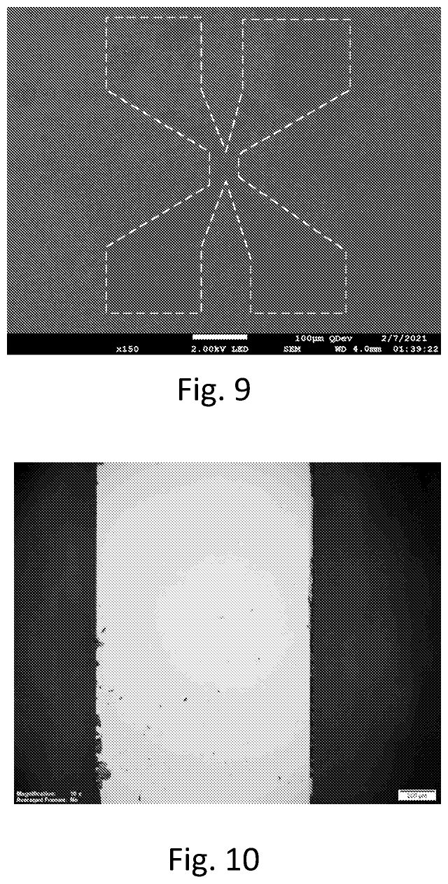

After 15 minutes, the titanium mask appears to have been fully removed, as can be seen in FIG. 10. The SEM image confirmed this observation.

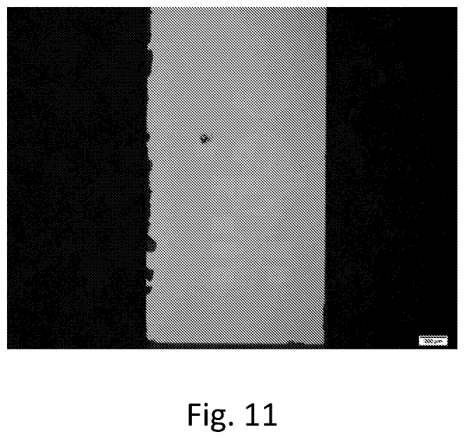

After 20 minutes, it was found that the etchant had begun to attack exposed aluminium in the regions in the regions without titanium coverage. The regions in which the aluminium had been attacked are visible as darker-grey regions in FIG. 11. The SEM image confirmed this observation.

The black speckles visible in the optical micrographs are fragments of dirt, introduced by handling the workpieces using tweezers.

### Comparative Example

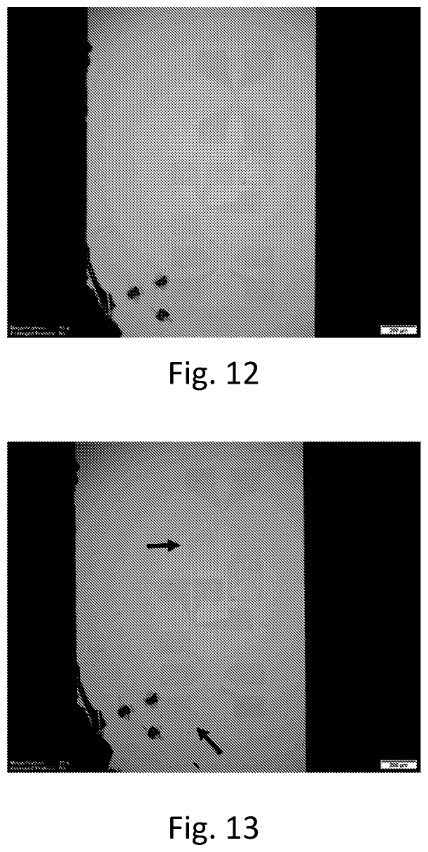

A workpiece of the type described in Example 2 was prepared. An optical micrograph of the workpiece was captured, and processed as previously described. The micrograph is shown in FIG. 12.

The workpiece was submerged in concentrated sulfuric acid at about room temperature. The workpiece was inspected by optical microscopy after 10, 100, and 700 seconds.

No visible changes to the Ti mask were observed after 10 seconds or 100 seconds.

A processed optical micrograph of the workpiece after a 700-second etch is shown in FIG. 13. Some titanium dioxide had been removed from the areas indicated by arrows, with the mask becoming at least partially transparent. However, large portion of the mask remained intact. The etch using sulfuric acid was considered unsuccessful due to the unevenness of the etch.

Three craters are visible in FIGS. 12 and 13. These craters were the result of the use of wire-bonding to provide an electrical connection for allowing anodic oxidation to be performed, and correspond to the positions of the wire bonds.

It will be appreciated that the above embodiments have been described by way of example only.

More generally, according to one aspect disclosed herein, there is provided a method comprising etching titanium dioxide selectively in the presence of aluminium oxide using an etchant. The etchant is an aqueous solution of a base and a hydroperoxide. It has surprisingly been found that a wet etch using a combination of a base and a hydroperoxide can remove titanium dioxide without excessively damaging aluminium oxide.

The etching may be performed by contacting the titanium dioxide and the aluminium oxide with the etchant.

Without wishing to be bound by theory, it is believed that the etchant converts the titanium dioxide into one or more relatively soluble titanium (IV) complexes. The complexes are believed to include at least one ligand derived from the hydroperoxide. Some of the complexes may further include one or more hydroxyl (OH) ligands and/or one or more aqua (H₂O) ligands.

The hydroperoxide may be any hydroperoxide which provides a source of one or more ligands capable of coordinating to titanium, selected from oxo ligands (O²⁻), superoxo ligands (O₂⁻), peroxo ligands (O₂²⁻), hydroperoxo ligands (ROOH), and peroxyl ligands (ROO—).

The hydroperoxide may be selected from hydrogen peroxide and a C1 to C4 alkyl hydroperoxide. Particularly preferably, the hydroperoxide may be hydrogen peroxide. An example of a C1 to C4 alkyl hydroperoxide is t-butyl hydroperoxide.

In implementations where the titanium dioxide is formed in situ, the peroxide may additionally act as an oxidizing agent.

The base adjusts the pH of the etchant. Aluminium oxide is susceptible to attack by acidic solutions, and avoiding such conditions may therefore contribute to the selectivity of the etchant. The base may also help to dissolve the titanium dioxide.

Reliably measuring the pH of a solution which includes a hydroperoxide may be difficult. For example, hydrogen peroxide interferes with the operation of pH meters (Kolczynski et al, J. Am. Chem. Soc 1957, 79, 3, 531-533). The apparent pH can deviate by 2 log units or even more from the true pH of the solution: a misleading pH reading can be obtained unless great care is taken to calibrate for the presence of the hydroperoxide.

The inventors believe that optimum selectivity may be obtained when the etchant is moderately basic. Increasing the pH may favour the formation of more soluble titanium (IV) complexes. However, it is predicted that an excessively high pH might make it more difficult to control the etch, as the rate of attack on the aluminium oxide might increase.

The nature of the base is not particularly limited, provided that an appropriate pH is obtained. The concentration of the base may be optimized by routine testing.

The base may be monobasic. The base may have a pk_{b} in the range 4.5 to 5.5. Particularly preferably, the base may be ammonia.

The base and the hydroperoxide may be present in the etchant at a molar ratio in the range 1:25 to 1:45. For example, the base and the hydroperoxide may be present in the etchant at a molar ratio in the range 1:30 to 1:40, or 1:34 to 1:38. In particular, the base and the hydroperoxide may be present in the etchant at a molar ratio of 1:36 to 1:37, or about 1:36.5.

The base may be present in the etchant at a concentration in the range 25 to 100 mM. Optionally, the base may be present in the etchant at a concentration in the range 30 to 70 mM, further optionally 50 to 60 mM.

The hydroperoxide may be present in the etchant at a concentration in the range 1 to 3 M. Optionally, the hydroperoxide may be present in the etchant at a concentration in the range 1.5 to 2.5 M, further optionally 1.8 to 2.2 M.

The temperature at which the etching is performed may be selected as desired. For example, the etching may be performed at a temperature of less than or equal to 30° C. Some semiconductor materials used in semiconductor-superconductor hybrid devices can degrade if subjected to high temperatures. Performing the etching at or below room temperature may help to avoid such degradation. Moreover, good selectivity has been observed in etches performed at room temperature.

The duration of the etch may be selected as appropriate depending upon the concentration of the reagents in the etchant, the temperature, and the thickness of the titanium or titanium dioxide layer to be removed.

The method may further comprise oxidising titanium to form the titanium dioxide.

The titanium may be oxidised in advance. A film of titanium with a thickness of up to about 7 nm may be oxidised by exposure to air. Alternatively or additionally, the titanium may be oxidised by anodic oxidation.

The titanium may be oxidised by exposure to water, oxygen, and/or the hydroperoxide. The titanium may be oxidised by contacting the titanium with the etchant. Since titanium can be readily converted into titanium dioxide in situ, the method provided herein is useful for etching titanium metal.

Part of the titanium may be oxidised in advance and part of the titanium may be oxidised in situ by exposure to the etchant. In implementations where titanium and/or titanium dioxide is used as a mask for controlling anodic oxidation of aluminium, this may allow a wider range of anodic oxidation conditions to be used since the anodic oxidation does not need to convert all of the titanium into titanium dioxide.

The etching may be performed in the presence of a semiconductor component. In such implementations, the aluminium oxide may be in the form of a layer covering the surface of the semiconductor component. The aluminium oxide layer may protect the semiconductor component from the etchant.

The semiconductor component may comprise a III-V semiconductor material, for example a material of Formula 1:

InAsₓSb₁₋ₓ (Formula 1)

where x is in the range 0 to 1. In other words, the semiconductor component may comprise indium antimonide (x=0), indium arsenide (x=1), or a ternary mixture comprising 50% indium on a molar basis and variable proportions of arsenic and antimony (0<x<1).

Another class of materials useful as the semiconductor component are II-VI semiconductor materials. Examples of II-VI semiconductor materials include cadmium telluride, mercury telluride, lead telluride and tin telluride.

The semiconductor component may be in the form of a nanowire. The semiconductor component may be in the form of a network of nanowires.

The semiconductor component may be in the form of a semiconductor heterostructure. The semiconductor heterostructure comprises a quantum well arranged between a lower barrier and an upper barrier. This structure is referred to as a heterostructure because the quantum well comprises a material which is different from the material(s) of the lower barrier and upper barrier. The materials of the lower barrier layer and the upper barrier layer may each be independently selected.

The configuration of the lower and upper barriers is not particularly limited, provided that these layers allow electrons to be trapped in the quantum well. The lower barrier may comprise one or more layers of one or more different materials. The upper barrier may comprise one or more layers of one or more different materials. Constructing a barrier from a plurality of layers may provide defect filtering, i.e. may reduce the effects of dislocations in the crystalline structure of the materials used.

The quantum well may comprise a layer of semiconductor material which has a relatively small band gap compared to the materials of the lower and upper barriers. Illustrative materials useful for forming quantum wells are described in, for example, Odoh and Njapba, “A Review of Semiconductor Quantum Well Devices”, Advances in Physics Theories and Applications, vol. 46, 2015, pp. 26-32; and S. Kasap, P. Capper (Eds.), “Springer Handbook of Electronic and Photonic Materials”, DOI 10.1007/978-3-319-48933-9_40.

The etching may be performed in the presence of a superconductor component. The aluminium oxide may cover the superconductor component, and may protect the superconductor component from the etchant. The nature of the superconductor is not particularly limited and may be selected as appropriate. The superconductor is typically an s-wave superconductor. Any of the various s-wave superconductors known in the art may be used. Examples include aluminium, indium, tin, and lead. In particular, the superconductor component may comprise aluminium.

The titanium dioxide may be arranged on the aluminium oxide. An aluminium component may be present under the titanium dioxide, with the aluminium oxide being between the aluminium component and the titanium dioxide.

The method may further comprise, before the etching:
forming a titanium mask over a layer of aluminium, wherein the titanium mask covers a first portion of the layer of aluminium and exposes a second portion of the layer of aluminium; and
   performing anodic oxidation,
   wherein the titanium mask protects the first portion of the layer of aluminium from being fully oxidized by the anodic oxidation; and
   wherein the second portion of the layer of aluminium is fully oxidized by the anodic oxidation, to form the aluminium oxide.

The layer of aluminium may extend over a semiconductor component. The semiconductor component may be a semiconductor heterostructure configured to host a 2-dimensional electron gas or a 2-dimensional hole gas.

The titanium mask may be formed by lift-off. In such implementations, the method further comprises:
forming a sacrificial mask over the layer of aluminium, the sacrificial mask having at least one opening;
depositing a layer of titanium on the sacrificial mask and in the at least one opening;
removing the sacrificial mask to remove selectively the titanium on the sacrificial mask, thereby forming the titanium mask; and
performing the anodic oxidation.

The mask may be formed by electron beam lithography. The layer of titanium may be grown by evaporation.

The method may further comprise, before forming the titanium mask, oxidising a partial thickness of the aluminium layer. Oxidising the partial thickness may comprise exposing the aluminium layer to oxygen and allowing a native oxide layer to form. Oxidising the partial thickness may further comprise performing anodic oxidation. When fabricating a semiconductor-superconductor hybrid device, for example, it is useful to grow a relatively thick aluminium layer since growing high-quality thin films is very challenging. Subsequently reducing the thickness of the film by partial oxidation may improve the superconducting properties of the aluminium layer. For example, thinner layers have higher critical magnetic fields than thicker layers.

The titanium dioxide may be in the form of a layer having a thickness of less than or equal to 5 nm.

The aluminium oxide may be in the form of a layer. The aluminium oxide may cover a surface of a substrate, e.g. a wafer of semiconductor material. One or more components may be present between the aluminium oxide and the surface of the substrate. The one or more components may, for example, comprise a semiconductor-superconductor hybrid structure. The thickness of the aluminium oxide layer may be selected such that, after the etch, the aluminium oxide layer has a thickness of at least 3 nm. This may provide good protection of components which are under the aluminium layer. For example, the aluminium oxide may be in the form of a layer having a thickness of at least 8 nm.

The method may further comprise, after the etching, cleaning the aluminium oxide using an acid solution, optionally a hydrogen fluoride solution. Contacting the aluminium oxide with the etchant may result in contamination of the surface. Cleaning the surface of the aluminium oxide layer using an acid solution may remove such contaminants.

The method may further comprise preparing the etchant by mixing an aqueous solution of the base, an aqueous solution of the hydroperoxide, and water. In such implementations, the aqueous solution of the base may have a pH in the range 10 to 13, and is included in the etchant at a ratio in the range 1:125 to 1:500, optionally 1:225 to 1:275, further optionally 1:245 to 1:255 by volume based on the total volume of the etchant. The aqueous solution of the hydroperoxide may have a concentration in the range 8 to 12 M and may be included in the etchant at a ratio in the range 1:3 to 1:6 by volume based on the total volume of the etchant.

The etchant may be obtainable by mixing an ammonia solution, a hydrogen peroxide solution, and water. The ammonia solution may be an aqueous solution comprising 25% ammonia by weight based on the weight of the ammonia solution. The hydrogen peroxide solution may be an aqueous solution comprising 30% hydrogen peroxide by weight based on the weight of the hydrogen peroxide solution. The ammonia solution, hydrogen peroxide solution, and water may be mixed at a ratio in the range (0.75 to 1.25):(37.5 to 62.5): 200 by volume, optionally 1:50:200.

In another aspect, there is provided an etchant for etching titanium dioxide, the etchant being an aqueous solution of ammonia and hydrogen peroxide, wherein the molar ratio of the ammonia to the hydrogen peroxide is in the range 1:34 to 1:38.

The ammonia may be present at a concentration in the range 50 to 60 mM and the concentration of the hydrogen peroxide may be in the range 1.8 to 2.2 M.

The etchant may consist essentially of an aqueous solution of ammonia and hydrogen peroxide, and in other words may consist essentially of a mixture of ammonia, hydrogen peroxide, and water. The etchant may be free of solutes other than the ammonia, the hydrogen peroxide, dissolved carbonate, and trace amounts of impurities. The etchant may include no more than 50 ppm, optionally 25 ppm of solutes other than the ammonia and the hydrogen peroxide.

Other variants or use cases of the disclosed techniques may become apparent to the person skilled in the art once given the disclosure herein. The scope of the disclosure is not limited by the described embodiments but only by the accompanying claims.

1. A method, comprising:
etching titanium dioxide selectively in the presence of aluminium oxide using an etchant,
wherein the etchant is an aqueous solution of a base and a hydroperoxide.

2. The method according to claim 1, wherein the hydroperoxide is selected from hydrogen peroxide and a C1 to C4 alkyl hydroperoxide.

3. The method according to claim 1, wherein the base is monobasic and has a pK_{b} in the range 4.5 to 5.5; optionally wherein the base is ammonia.

4. The method according to claim 1, wherein the base and the hydroperoxide are present in the etchant at a molar ratio in the range 1:25 to 1:45, optionally 1:30 to 1:40, further optionally 1:34 to 1:38.

5. The method according to claim 1, wherein the base is present in the etchant at a concentration in the range 25 to 100 mM, optionally 30 to 70 mM, further optionally 50 to 60 mM.

6. The method according to claim 1, wherein the hydroperoxide is present in the etchant at a concentration in the range 1 to 3 M.

7. The method according to claim 1, wherein the etching is performed at a temperature of less than or equal to 30° C.

8. The method according to claim 1, further comprising oxidising titanium to form the titanium dioxide, and wherein:
i) the titanium is oxidised by anodic oxidation, or
ii) part of the titanium is oxidised by anodic oxidation and part of the titanium is oxidised by exposure to water, oxygen, and/or the hydroperoxide.

9. The method according to claim 1, wherein the etching is performed in the presence of a semiconductor component and/or a superconductor component, and the aluminium oxide protects the semiconductor component and/or superconductor component from the etchant.

10. The method according to claim 1, wherein:
i) the titanium dioxide is arranged on the aluminium oxide; and/or
ii) the titanium dioxide has a thickness of less than or equal to 5 nm; and/or
iii) the aluminium oxide has a thickness of at least 8 nm.

11. The method according to claim 1, further comprising, after the etching, cleaning the aluminium oxide using an acid solution, optionally a hydrogen fluoride solution.

12. The method according to claim 1, further comprising preparing the etchant by mixing an aqueous solution of the base, an aqueous solution of the hydroperoxide, and water.

13. An etchant for etching titanium dioxide, the etchant being an aqueous solution of ammonia and hydrogen peroxide, wherein the molar ratio of the ammonia to the hydrogen peroxide is in the range 1:34 to 1:38.

14. The etchant according to claim 13, wherein the ammonia is present at a concentration in the range 50 to 60 mM and the concentration of the hydrogen peroxide is in the range 1.8 to 2.2 M.

15. The etchant according to claim 13, wherein the etchant includes no more than 50 ppm of solutes other than the ammonia, the hydrogen peroxide, and carbonate, by weight based on the total weight of the etchant.

16. The method according to claim 2, wherein the hydroperoxide is hydrogen peroxide and wherein the hydroperoxide is present in the etchant at a concentration in the range 1.8 to 2.2 M.

17. The method according to claim 12, wherein:
the aqueous solution of the base has a pH in the range 10 to 13, and is included in the etchant at a ratio in the range 1:125 to 1:500, optionally 1:225 to 1:275, further optionally 1:245 to 1:255 by volume based on the total volume of the etchant.

18. The method according to claim 12, wherein:
the aqueous solution of the hydroperoxide has a concentration in the range 8 to 12 M and is included in the etchant at a ratio in the range 1:3 to 1:6 by volume based on the total volume of the etchant.

19. A hybrid semiconductor component comprising:
an aluminium component; and
a titanium dioxide layer deposited over the aluminium component, the titanium dioxide being selectively etched with an aqueous solution of a base and a hydroperoxide, the titanium dioxide layer being formed from oxidising titanium by exposure to air, by anodic oxidation, or by an etchant comprising an aqueous solution of a base and a hydroperoxide.

20. The hybrid semiconductor component of claim 19, further comprising an aluminium oxide layer extending between the aluminium component and the titanium dioxide layer.
